(19) United States
(12) Patent Application Publication
(10) Pub. No.: US 2015/0293201 A1
(43) Pub. Date: Oct. 15, 2015

(54) Medical Imaging System

(71) Applicants: Bernd Assmann, Furth (DE); Jürgen Rößler, Erlangen (DE)

(72) Inventors: Bernd Assmann, Furth (DE); Jürgen Rößler, Erlangen (DE)

(21) Appl. No.: 14/685,393

(22) Filed: Apr. 13, 2015

(30) Foreign Application Priority Data
Apr. 14, 2014 (DE) 102014207124.0

(51) Int. Cl. G01R 33/565; H01Q 1/24

(52) U.S. Cl. CPC G01R 33/56509; H01Q 1/24

(57) ABSTRACT

A medical imaging system includes a detector unit, and a patient receiving area at least partly surrounded by the detector unit. The detector unit defines an imaging area within the patient receiving area. The medical imaging system also includes a movement detection unit for detecting a movement such as a heart movement and/or a breathing movement of a patient able to be positioned within the patient receiving area. The movement detection unit includes a radar unit with a radar transmit unit and a radar receive unit. The radar transmit unit includes at least one transmit antenna, and the radar receive unit includes at least one receive antenna. The at least one transmit antenna and/or the at least one receive antenna is disposed outside the imaging area.

This application claims the benefit of DE 10 2014 207 124.0, filed on Apr. 14, 2014, which is hereby incorporated by reference in its entirety.

### BACKGROUND

The present embodiments relate to a medical imaging system.

Medical imaging (e.g., magnetic resonance imaging) may include a number of transmit-receive cycles that are combined through post-processing into an image. For the areas of a patient's body that are moving (e.g., as a result of a patient's heartbeat and/or breathing), the detection of the image for the individual cycles is to take place in the same phase of the movement. For this to be done, trigger signals that specify a trigger time for image detection for magnetic resonance imaging are derived from the body movement. For example, to detect image data of a heart area of the patient, the data detected by the medical imaging system is to be synchronized to the R-wave of an EKG signal of the patient, so that the image data detected at different times has the same heart phase.

Previously external measurement facilities have been used to detect a movement of the patient. For example, electrodes are used for detecting a heart movement of the patient during medical imaging. These external measurement facilities, however, demand extensive preparation from operating personnel (e.g., a corresponding fitting of the external measurement device to the patient).

### SUMMARY AND DESCRIPTION

The scope of the present invention is defined solely by the appended claims and is not affected to any degree by the statements within this summary.

The present embodiments may obviate one or more of the drawbacks or limitations in the related art. For example, a reliable detection of a heart movement and/or a lung movement of a patient is provided.

A medical imaging system includes a detector unit and a patient receiving area at least partly surrounded by the detector unit. The detector unit defines an imaging area within the patient receiving area. The medical imaging system also includes a movement detection unit for detecting a movement (e.g., a heart movement and/or a breathing movement) of a patient able to be positioned within the patient receiving area. The movement detection unit includes a radar unit with a radar transmit unit and a radar receive unit.

The radar transmit unit includes at least one transmit antenna, and the radar receive unit includes at least one receive antenna. The at least one transmit antenna and/or the at least one receive antenna are disposed outside the imaging area. The imaging area may be an area within the patient receiving area in which the part of the patient to be examined is to be located for detection of image data. The imaging area may include an iso-center of the detector unit. If, for example, the medical imaging system is formed by a computed tomography system, the iso-center includes an axis of rotation of the detector unit, for example. If, for example, the medical imaging system is formed by a magnetic resonance system, the iso-center includes the point with the greatest magnetic field homogeneity. The imaging area in a magnetic resonance system includes, for example, an area with a homogeneous magnetic field. The at least one transmit antenna and/or the at least one receive antenna is disposed on an axis at right angles to the main magnetic field. The axis runs outside the iso-center and, for example, also outside the imaging area.

The radar unit adversely affecting the image data detection and also the radar unit adversely affecting the data detection through the image data detection by the medical imaging device may be advantageously reduced and/or prevented. Noise signals that may adversely affect the image data detection may be caused by the at least one transmit antenna and/or the at least one receive antenna. Because the at least one transmit antenna and/or the at least one receive antenna are disposed outside the imaging area, these noise signals lie outside the image detection area of the medical imaging system and thus do not cause any disruption to image data detection.

In one embodiment, the at least one receive antenna is embodied and/or disposed separately from the at least one transmit antenna. An arrangement of the at least one transmit antenna and an arrangement of the at least one receive antenna may advantageously be harmonized with one another, so that a detection of radar signals that are reflected from objects (e.g., from a patient within the imaging area of the patient receiving area) will be maximized by the at least one receive antenna. In addition, an arrangement of the at least one transmit antenna and/or of the at least one receive antenna outside the imaging area may be achieved in a constructively simple manner.

The medical imaging system also has a housing unit that surrounds the patient receiving area. The at least one transmit antenna and/or the at least one receive antenna is disposed within the housing unit. This enables an advantageous arrangement of the at least one transmit antenna and/or the at least one receive antenna, in which the antennas may be prevented from obstructing the patient during his or her introduction into the patient receiving area and/or his or her withdrawal from the patient receiving area, to be achieved. The housing unit surrounds the patient receiving area (e.g., in a cylindrical shape). An embodiment differing from the shape may also be provided.

In one embodiment, the patient receiving area has two end areas. The at least one transmit unit is disposed within a housing area of the housing unit that surrounds the first end area, and the at least one receive antenna is disposed within a housing area of the housing unit that surrounds the second end area. This enables an advantageous arrangement of the at least one transmit antenna and/or the at least one receive antenna to be achieved in which the antennas may be prevented from obstructing the patient during his or her introduction into the patient receiving area and/or his or her withdrawal from the patient receiving area. This arrangement of the at least one transmit unit and the at least one receive unit enables the radar unit to detect a movement in an especially large area within the patient receiving area (e.g., of the imaging area). The two end areas of the patient receiving area may be disposed in the longitudinal extension and/or in the direction of introduction at opposite ends of the patient receiving area.

If the at least one transmit antenna transmits a radar signal that fans out, a movement in a large area of the imaging area may be detected by the radar signal. This provides that the moving subarea of the patient (e.g., a heart area and/or a lung area) does not have to be disposed exactly in the iso-center, since a larger recording area is made available by the radar signal of the transmit antenna that is larger than the iso-center of the medical imaging system. A radar signal that fans out may be understood as a radar signal that spreads out in a conical shape in the propagation direction of the radar signal.

In a further embodiment, the transmit unit has a focusing unit that aligns the at least one transmit antenna such that a radar signal transmitted by the at least one transmit antenna is directed to a target area of the patient. The radar signal may be directed to a target area of the patient independent of the position of the patient. The focusing unit may have a mechanical device and/or an electronic focusing device that carries out an adjustment of the radar signal to a desired target area of the patient. The target area of the patient may include a heart area and/or a lung area of the patient.

In one embodiment, the focusing unit selects the position of the target area of the patient as a function of at least one patient registration parameter. The at least one patient registration parameter may be entered into the medical imaging system before a medical imaging examination by a member of the operating personnel looking after the medical imaging examination. The at least one patient registration parameter may be a position of the patient, a size of the patient and/or further parameters appearing sensible to the person skilled in the art.

The focusing unit may select a position of the target area of the patient as a function of monitoring data. In one embodiment, the monitoring data includes data of a monitoring unit by which a position of the patient may be monitored and/or detected. The monitoring unit may, for example, include a camera and/or further monitoring sensors.

### BRIEF DESCRIPTION OF THE DRAWINGS

FIG. 1 shows an embodiments of a medical imaging system; and

FIG. 2 shows an alternate embodiment of an image detection unit of the medical imaging system of FIG. 1.

### DETAILED DESCRIPTION

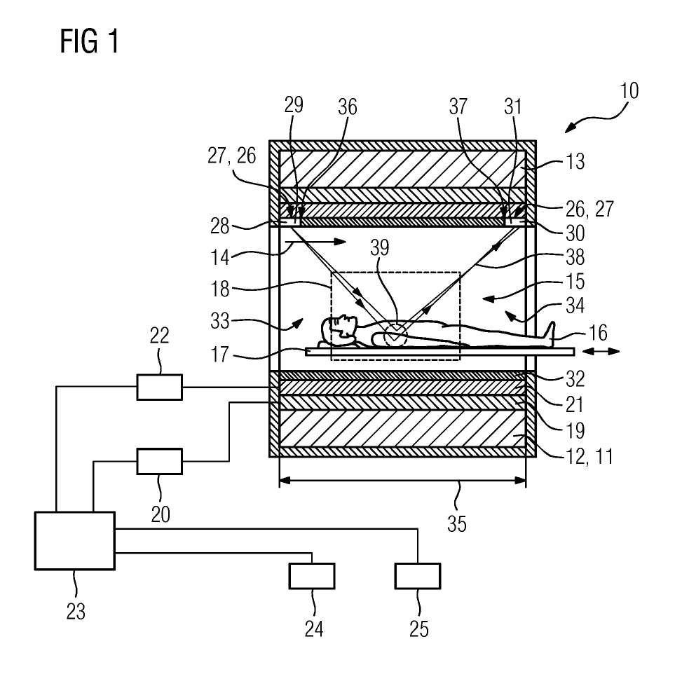

FIG. 1 shows a schematic diagram of one embodiment of a medical imaging system 10. In the present exemplary embodiment the medical imaging system 10 is formed by a magnetic resonance system. In the embodiment of the medical imaging system 10 differing therefrom, the system may also be formed by a computed tomography system and/or a PET (Positron Emission Tomography) system and/or further imaging facilities 10 appearing sensible to the person skilled in the art.

The magnetic resonance system includes a detector unit 11 that has a magnet unit 12 with a superconducting main magnet 13 for creating a strong and, for example, constant main magnetic field 14. In addition, the magnetic resonance system includes the patient receiving area 15 for receiving a patient 16. The patient receiving area 15 is embodied in the present exemplary embodiment in the shape of a cylinder and is surrounded in a cylindrical shape in a circumferential direction by the magnet unit 12. An embodiment of the patient receiving area 15 differing therefrom may be provided. The patient 16 may be pushed by a patient support device 17 of the magnetic resonance system into the patient receiving area 15.

An imaging area 18 that includes an especially homogeneous and constant magnetic field is created within the patient receiving area 15 by the superconducting main magnet 13. Also disposed within this imaging area 18 is the iso-center of the magnet unit. The imaging area 18 may be disposed in a center of the patient receiving area 15.

The magnet unit 12 also includes a gradient coil unit 19 for creating magnetic field gradients that are used for local encoding during imaging. The gradient coil unit 19 is controlled by a gradient control unit 20 of the magnetic resonance system. The magnet unit 12 further includes a radio-frequency antenna unit 21 and a radio-frequency antenna control unit 22 for exciting a polarization that is set up in the main magnetic field 14 created by the main magnet 13. The radio-frequency antenna unit 21 is controlled by the radio-frequency antenna control unit 22 and emits radio-frequency magnetic resonance sequences into an examination area that is essentially formed by a patient receiving area 15 of the magnetic resonance system.

To control the main magnet 13, the gradient control unit 20, and to control the radio-frequency antenna control unit 22, the magnetic resonance system has a control unit 23 formed by a processing unit. The control unit 23 centrally controls the magnetic resonance system, such as carrying out a predetermined imaging gradient echo sequence, for example. In addition, the control unit 23 includes an evaluation unit not shown in any greater detail for evaluation of image data. Control information such as imaging parameters, for example, and also reconstructed magnetic resonance images may be displayed on a display unit 24 (e.g., on at least one monitor) of the magnetic resonance system for an operator. In addition, the magnetic resonance system includes an input unit 25, by which the information and/or parameters may be entered by an operator during a measurement process.

The magnetic resonance system includes a movement detection unit 26 with a radar unit 27 for detecting a heart movement and/or a breathing movement of the patient 16. The radar unit 27 includes a radar transmit unit 28 with at least one the transmit antenna 29. In the present exemplary embodiment, the radar transmit unit 28 includes a single transmit antenna 29. The radar transmit unit 28 may also have two or more transmit antennas 29. In addition, the radar unit 27 includes a radar receive unit 30 with at least one receive antenna 31. In the present exemplary embodiment, the radar receive unit 30 includes a single receive antenna 31. The radar receive unit 30 may also include two or more receive antennas 31.

The transmit antenna 29 and also the receive antenna 31 are disposed outside the imaging area 18, so that an undesired disruption of magnetic resonance imaging because of the radar unit 27 and also an undesired disruption of the movement detection by radar unit 27 because of magnetic resonance imaging are prevented. The transmit antenna 29 and the receive antenna 31 are disposed within a housing unit 32 of the magnetic resonance system surrounding the patient receiving area 15. The housing unit 32 surrounds the magnet unit 12 and thus also the patient receiving area 15 in a cylindrical shape.

The transmit antenna 29 and the receive antenna 31 are embodied separately and are also disposed separately from one another within the housing unit 32. The patient receiving area 15 has two end areas 33, 34. The two end areas 33, 34 are disposed at opposite ends of the patient receiving area 15 in a longitudinal extension 35 of the patient receiving area 15. A direction of the longitudinal extension 35 of the patient receiving area 15 also corresponds to a direction of an introduction movement of the patient support device 17 into the patient receiving area 15. A first end area 33 of the two end areas 33, 34 of the patient receiving area 15 is surrounded by a first housing area 36 of the housing unit 32. The transmit antenna 29 is disposed in the first housing area 36. A second end area 34 of the two end areas 33, 34 of the patient receiving area 15 is surrounded by a second housing area 37 of the housing unit 32. The receive antenna 31 is disposed in the second housing area 37.

The transmit antenna 29 is disposed in this case within the first housing area 36 such that a radar signal 38 transmitted by the transmit antenna 29 strikes a target area 39 disposed within the patient receiving area 15 (e.g., the heart area and/or the lung area of the patient 16). The radar signal 38 is scattered and/or reflected by this target area 39 and is detected by the receive antenna 31. For this purpose, the receive antenna 31 is also aligned within the second housing area 37 such that a radar signal 38 scattered and/or reflected by a target area 39 may be detected by the receive antenna 31. The transmit antenna 29 is embodied such that the transmitted radar signal 38 fans out. In this way, a particularly large target area 39 may be detected by the radar signal 38.

In the detected radar signals 38 of the receive unit 30, a heart movement of a patient 26 may be separated from a lung movement (e.g., a breathing movement) of the patient 16. The radar signals 38 detected by the receive antenna 31 reflect the movements of the organs in the target area 39 of the patient 16, which change over time. A movement of the lungs, because of the breathing of the patient 16, is represented as a sinusoidal curve of the detected radar signals 38 as a function of the detection time. The movement of the lungs is overlaid with the movement of the heart. The heart movement represents a higher-frequency signal curve of the detected radar signals 38 as a function of the detection time with respect to the lung movement. The detected radar signals 38 as a function of the detection time may also be overlaid with an essentially constant component that is caused, for example, by a radar signal portion reflected from the patient support device 17.

To separate the radar signals 38 caused and detected by the heart movement of the patient 16 from the radar signals 38 caused and detected by a lung movement of the patient 16, the radar unit has an evaluation unit not shown in any greater detail. The separated signals of the heart movement will subsequently be conveyed via a data transmission unit not shown in any greater detail to the control unit 23 and will be used there for triggering the magnetic resonance imaging.

As well as a reflected portion of the radar signal 38, an absorption-related portion of the radar signal 38 may also be detected. The absorption-related portion of the radar signal 38 is produced indirectly from the reflected portion of the radar signal 38.

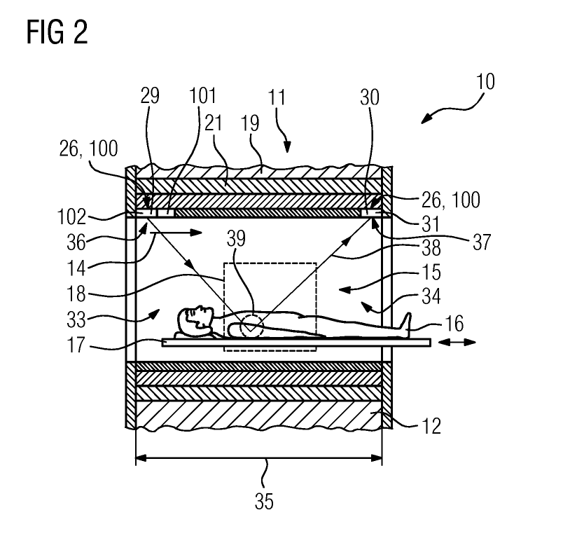

FIG. 2 shows an alternate exemplary embodiment of the radar unit 100. Components, features and functions that essentially remain the same are basically labeled with the same reference numbers. The description given below is essentially restricted to the differences from the exemplary embodiment depicted in FIG. 1. See the description of the exemplary embodiment in FIG. 1 as regards components, features and functions that remain the same.

As an alternative to the embodiment of the radar unit 27 in FIG. 1, the radar unit 100 depicted in FIG. 2 includes a focusing unit 101 that aligns the transmit antenna 29 such that a radar signal 38 transmitted by the transmit antenna 29 is directed to the target area 39 of the patient 16. The focusing unit 101 is, for example, part of the transmit unit 102.

The focusing unit 101 selects a position of the target area 39 of the patient 16 as, for example, a function of at least one patient registration parameter and/or as a function of a monitoring parameter. The at least one patient registration parameter may be entered into the medical imaging system before a medical imaging examination using an input unit 25 by a member of the operating personnel looking after the medical imaging examination. In this case, the at least one patient registration parameter may be a position of the patient 16, a size of the patient 16, and/or further parameters sensible to the person skilled in the art. The monitoring data may include data of a monitoring unit not shown in any greater detail. Using the monitoring unit, a position of the patient 16 is monitored and/or detected. The monitoring unit may include a camera and/or further monitoring sensors, for example.

The focusing unit 101 has the required mechanical and/or electronic focusing not shown in any greater detail, which sets the radar signal 38 to a desired target area 39 of the patient 16.

A further embodiment of the radar unit 100 corresponds to the embodiment of the radar unit 27 in FIG. 1.

Although the invention has been illustrated in greater detail and described by the exemplary embodiment, the invention is not restricted by the disclosed examples. Other variations may be derived herefrom by the person skilled in the art without departing from the scope of protection.

The elements and features recited in the appended claims may be combined in different ways to produce new claims that likewise fall within the scope of the present invention. Thus, whereas the dependent claims appended below depend from only a single independent or dependent claim, it is to be understood that these dependent claims may, alternatively, be made to depend in the alternative from any preceding or following claim, whether independent or dependent. Such new combinations are to be understood as forming a part of the present specification.

While the present invention has been described above by reference to various embodiments, it should be understood that many changes and modifications can be made to the described embodiments. It is therefore intended that the foregoing description be regarded as illustrative rather than limiting, and that it be understood that all equivalents and/or combinations of embodiments are intended to be included in this description.

1. A medical imaging system comprising:
a detector;
a patient receiving area at least partly surrounded by the detector, wherein the detector defines an imaging area within the patient receiving area; and
a movement detection unit for detecting a movement of a patient, the movement detection unit being positionable within the patient receiving area, wherein the movement detection unit comprises a radar, the radar comprising a radar transmit antenna and a radar receive antenna,
wherein the at least one transmit antenna, the at least one receive antenna, or the at least one transmit antenna and the at least one receive antenna are disposed outside the imaging area.

2. The medical imaging system of claim 1, wherein the at least one receive antenna is configured, disposed, or configured and disposed separated from the at least one transmit antenna.

3. The medical imaging system of claim 1, further comprising a housing that surrounds the patient receiving area,
wherein the at least one transmit antenna, the at least one receive antenna, or the at least one transmit antenna and the at least one receive antenna are disposed within the housing.

4. The medical imaging system of claim 3, wherein the patient receiving area has two end areas,
wherein the at least one transmit antenna is disposed within a housing area of the housing that surrounds a first end area of the two end areas, and the at least one receive antenna is disposed within a housing area of the housing that surrounds a second end area of the two end areas.

5. The medical imaging system of claim 1, wherein the at least one transmit antenna transmits a radar signal that fans out.

6. The medical imaging system of claim 1, wherein the transmit unit comprises a focusing unit that aligns the at least one transmit antenna such that a radar signal transmitted by the at least one transmit antenna is directed to a target area of the patient.

7. The medical imaging system of claim 6, wherein the focusing unit selects a position of the target area of the patient as a function of at least one patient registration parameter.

8. The medical imaging system of claim 6, wherein the focusing unit selects a position of the target area of the patient as a function of monitoring data.

9. The medical imaging system of claim 6, wherein the target area of the patient comprises a lung area, a heart area, or the lung area and the heart area of the patient.

10. The medical imaging system of claim 2, further comprising a housing that surrounds the patient receiving area,
wherein the at least one transmit antenna, the at least one receive antenna, or the at least one transmit antenna and the at least one receive antenna are disposed within the housing.

11. The medical imaging system of claim 10, wherein the patient receiving area has two end areas,
wherein the at least one transmit antenna is disposed within a housing area of the housing that surrounds a first end area of the two end areas, and the at least one receive antenna is disposed within a housing area of the housing that surrounds a second end area of the two end areas.

12. The medical imaging system of claim 4, wherein the at least one transmit antenna transmits a radar signal that fans out.

13. The medical imaging system of claim 12, wherein the radar comprises a focusing unit that aligns the at least one transmit antenna such that a radar signal transmitted by the at least one transmit antenna is directed to a target area of the patient.

14. The medical imaging system of claim 12, wherein the focusing unit selects a position of the target area of the patient as a function of at least one patient registration parameter.

15. The medical imaging system of claim 7, wherein the focusing unit selects a position of the target area of the patient as a function of monitoring data.

16. The medical imaging system of claim 7, wherein the target area of the patient comprises a lung area, a heart area, or the lung area and the heart area of the patient.
